(19) United States
(12) Patent Application Publication
(10) Pub. No.: US 2026/0247982 A1
(43) Pub. Date: Aug. 20, 2026

(54) SEMICONDUCTOR PACKAGE, SEMICONDUCTOR MODULE, SEMICONDUCTOR DEVICE, AND SEMICONDUCTOR PACKAGE MANUFACTURING METHOD

(71) Applicant: SONY SEMICONDUCTOR SOLUTIONS CORPORATION, Kanagawa (JP)

(72) Inventors: Hirohisa YASUKAWA, Kanagawa (JP); Hiroyuki SHIGETA, Kanagawa (JP)

(73) Assignee: SONY SEMICONDUCTOR SOLUTIONS CORPORATION, Kanagawa (JP)

(21) Appl. No.: 19/110,389

(22) PCT Filed: Jul. 4, 2023
(86) PCT No.: PCT/JP2023/024723

§ 371 Date: Mar. 10, 2025

(30) Foreign Application Priority Data
Sep. 22, 2022 (JP) 2022-150838
Nov. 11, 2022 (JP) 2022-180705

(51) Int. Cl. H10W 42/20; H10W 90/00; H10W 90/10; H10W 90/22

(52) U.S. Cl. CPC H10W 42/267; H10W 42/276; H10W 90/401; H10W 90/724; H10W 42/273; H10W 90/10; H10W 90/22

(57) ABSTRACT

Disclosed herein is a semiconductor package including a semiconductor chip configured to have one of two surfaces thereof mounted with a circuit, the circuit formation surface constituting a circuit formation surface, a first shield layer configured to cover a side of the semiconductor chip and the other surface thereof, and a second shield layer configured to cover the circuit formation circuit.

### TECHNICAL FIELD

The present disclosure relates to semiconductor package, semiconductor module, electronic device, and semiconductor package manufacturing method. This application claims the benefit of Japanese Priority Patent Application JP 2022-180705 filed Nov. 11, 2022, the entire contents of which are incorporated herein by reference.

The present technology relates to a semiconductor package. More particularly, the technology relates to a chip-size semiconductor package, a semiconductor module, a semiconductor device, and a semiconductor package manufacturing method.

### BACKGROUND ART

In the past, shields have been used in various semiconductor packages and electronic devices to protect their circuits from electromagnetic noise. For example, there has been proposed a semiconductor package in which shield layers are formed on back and side surfaces of a semiconductor chip of which a front surface opposite to the back surface is the circuit surface (e.g., see PTL 1).

### CITATION LIST

### Patent Literature

PTL 1: JP 2010-103574

### SUMMARY

### Technical Problem

According to the above-mentioned existing technology, the back and side surfaces of the semiconductor chip are covered with shield layers to protect the circuits in the chip from electromagnetic noise. In this semiconductor package, however, the surface of the semiconductor chip, i.e., the circuit surface thereof, is not shielded. Thus, if electro-magnetic noise occurs in a manner propagating from the front surface to the back surface, there may be a problem of the electrical characteristics of the circuits being degraded by EMI (Electro Magnetic Interference).

The present technology has been devised in view of the above circumstances, and it is desirable to improve resistance of a semiconductor package including a semi-conductor chip to EMI.

### Solution to Problem

According to a first mode of this technology, there is provided a semiconductor package including semiconductor chip configured to have one of two surfaces thereof mounted with a circuit, the circuit formation surface constituting a circuit formation surface, a first shield layer configured to cover a side of the semiconductor chip and the other surface thereof, and a second shield layer configured to cover the circuit formation circuit, as well as a method of manufacturing the semiconductor package. This provides an effect of improving the resistance of the circuits in the semiconductor package to EMI.

Also, according to the first mode of the present technology, the semiconductor package may further include an under-bump metal, in which the second shield layer includes part of a seed layer for growing the under-bump metal. This provides an effect of obtaining the shield layers by etching the seed layer.

Also, according to the first mode of the present technology, the semiconductor package may further include an insulating layer configured to cover the circuit formation surface, in which the second shield layer covers the insulating layer except for a predetermined region around the under-bump metal as viewed from a direction perpendicular to the semiconductor chip. This provides an effect of insulating the under-bump metal from the surroundings.

Also, according to the first mode of the present technology, the semiconductor package may further include a first redistribution layer formed outside of a protection area as part of the circuit formation surface, in which the second shield layer includes a second redistribution layer that covers the shielding region and is connected to a ground. This provides an effect of improving the resistance of the circuits on the protection area to EMI.

According to a second mode of the present technology, there is provided a semi-conductor module including a semiconductor package including a first semiconductor chip configured to have one of two surfaces thereof mounted with a circuit, the circuit formation surface constituting a circuit formation surface, a first shield layer configured to cover a side of the semiconductor chip and the other surface thereof, and a second shield layer configured to cover the circuit formation circuit, and a substrate configured to have the semiconductor package mounted thereon. This provides an effect of improving the resistance of the circuits in the semiconductor module to EMI.

Also, according to the second mode of the present technology, the semiconductor module may further include a signal via configured to penetrate the substrate, and multiple ground vias configured to penetrate the substrate in a manner surrounding the signal via as viewed from a direction perpendicular to the substrate. This provides an effect of further improving the resistance to EMI.

Also, according to the second mode of the present technology, the semiconductor module may further include a first circuit formed in the first semiconductor chip, and a second circuit configured to generate noise, in which the first circuit and the second circuit are each connected to a different ground. This provides an effect of improving the resistance of the first circuit to EMI.

Also, according to the second mode of the present technology, the second circuit may be formed in the substrate. This provides an effect of inhibiting the degradation of electrical characteristics to the noise coming from the substrate side.

Also, according to the second mode of the present technology, the semiconductor package and the second circuit may be disposed on a surface of the substrate. This provides an effect of inhibiting the degradation of the electrical characteristics of the circuits on the circuits due to noise.

Also, according to the second mode of the present technology, the semiconductor module may further include a shield configured to surround the semiconductor package as viewed from a direction perpendicular to the substrate. This provides an effect of further improving the resistance to EMI.

Also, according to the second mode of the present technology, the substrate may include a wiring layer configured to be mounted with the semiconductor package in a predetermined position on one of two surfaces of the substrate, a projecting section configured to project in a direction perpendicular to the other surface of the substrate, a first shield layer configured to cover an inner wall of the projecting section, and a signal via configured to penetrate the projecting section. This provides an effect of allowing the semiconductor module to connect electrically to an external device or external circuits.

Also, according to the second mode of the present technology, the substrate may further include a heat dissipating section disposed in a position corresponding to the predetermined position on the other surface of the substrate, and a ground via configured to penetrate the heat dissipating section and have ground potential. This provides an effect of improving heat dissipation performance.

Also, according to the second mode of the present technology, the semiconductor module may further include an integrated circuit disposed on the other surface of the substrate, in which the wiring layer includes a second shield layer, and the integrated circuit is surrounded by a portion of the projecting section as viewed from a direction perpendicular to the other surface of the substrate. This provides an effect of improving the resistance to EMI.

Also, according to the second mode of the present technology, the semiconductor module may further include a second semiconductor chip mounted on an inner wall of the projecting section. This provides an effect of improving the electrical characteristics.

Also, according to the second mode of the present technology, the substrate may further include a wiring layer configured to have the semiconductor package mounted on one of two surfaces of the substrate, a connector mounted on the other surface of the substrate in a manner projecting in a direction perpendicular to the other surface, and a shield layer configured to cover an inner wall of the connector. This provides an effect of improving reworkability.

Also, according to a third mode of the present technology, there is provided an electronic device including a semiconductor package including a semiconductor chip configured to have one of two surfaces thereof mounted with a circuit, the circuit formation surface constituting a circuit formation surface, a first shield layer configured to cover a side of the semiconductor chip and the other surface thereof, and a second shield layer configured to cover the circuit formation circuit, and a substrate configured to have the semiconductor chip mounted thereon. This provides an effect of improving the resistance of the circuits in the electronic device to EMI.

### Advantageous Effects of Invention

The back and side surfaces of the semiconductor chip are covered by the shield layer, with the shield layer also covering the circuit formation surface (surface). This makes the resistance to EMI higher than if only the back and side surfaces are covered by the shield layer.

### BRIEF DESCRIPTION OF DRAWINGS

FIG. 1 includes a cross sectional view and a bottom view depicting a con-figuration example of a semiconductor package as a first embodiment of the present technology.

FIG. 2 is an exemplary bottom view of the semiconductor package as the first embodiment of the present technology.

FIG. 3 explains a set of views of steps up to application of a resist in the first embodiment of the present technology.

FIG. 4 explains a set of views of steps up to formation of solder balls in the first embodiment of the present technology.

FIG. 5 explains a set of views of steps up to the formation of a shield layer on the back and side surfaces of the first embodiment of the present technology.

FIG. 6 is an exemplary flowchart describing an exemplary method of manufacturing the semiconductor package as the first embodiment of the present technology.

FIG. 7 is a cross sectional view depicting a configuration example of a semi-conductor package as a second embodiment of the present technology.

FIG. 8 is an exemplary bottom view of the semiconductor package as the second embodiment of the present technology.

FIG. 9 is a cross sectional view depicting a configuration example of a semi-conductor module as a third embodiment of the present technology.

FIG. 10 is a cross sectional view depicting a configuration example of a semi-conductor module as a fourth embodiment of the present technology.

FIG. 11 is a cross sectional view depicting a configuration example of a semi-conductor module as a fifth embodiment of the present technology.

FIG. 12 is a block diagram depicting a configuration example of the semi-conductor module as the fifth embodiment of the present technology.

FIG. 13 is a cross sectional view depicting another arrangement example of a digital circuit in the fifth embodiment of the present technology.

FIG. 14 is a cross sectional view depicting a configuration example of a semi-conductor module as a sixth embodiment of the present technology.

FIG. 15 is an exemplary top view of the semiconductor module as the sixth embodiment of the present technology.

FIG. 16 is an exemplary perspective view of an electronic device as a seventh embodiment of the present technology.

FIG. 17 is a block diagram depicting a configuration example of the electronic device as the seventh embodiment of the present technology.

FIG. 18 is a cross sectional view depicting a configuration example of a semi-conductor module as an eighth embodiment of the present technology.

FIG. 19 is an exemplary bottom view of a substrate in the eighth embodiment of the present technology.

FIG. 20 is a cross sectional view depicting a configuration example of a semi-conductor module as a first modification of the eighth embodiment of the present technology.

FIG. 21 is an exemplary bottom view of a substrate in the first modification of the eighth embodiment of the present technology.

FIG. 22 is a cross sectional view depicting a configuration example of a semi-conductor module as a second modification of the eighth embodiment of the present technology.

FIG. 23 is a cross sectional view depicting a configuration example of a semi-conductor module as a ninth embodiment of the present technology.

FIG. 24 is an exemplary bottom view of a substrate in the ninth embodiment of the present technology.

FIG. 25 is a block diagram depicting an example of schematic configuration of a vehicle control system.

FIG. 26 is a diagram depicting an example of an installation position of an imaging section.

### DESCRIPTION OF EMBODIMENTS

Preferred embodiments for implementing the present technology (referred to as the embodiments hereunder) are described below. The description will be given under the following headings in this order.
1. First embodiment (an example in which a shield layer is formed on a circuit formation surface)
2. Second embodiment (an example in which a redistribution layer is formed as a shield layer on the circuit formation surface)
3. Third Embodiment (an example in which a semiconductor package with the shield layer formed on the circuit formation surface is mounted)
4. Fourth Embodiment (an example in which the shield layer is formed on the circuit formation surface, with through vias coaxially structured)
5. Fifth Embodiment (an example in which the shield layer is formed on the circuit formation surface, with circuit grounding separated)
6. Sixth Embodiment (an example in which the shield layer is formed on the circuit formation surface, with shields disposed)
7. Seventh Embodiment (an example in which an electronic device is furnished with a semiconductor package having the shield layer formed on the circuit formation surface)
8. Eighth Embodiment (an example in which the semiconductor package having the shield layer formed on the circuit formation surface is mounted on a substrate fitted with a heat dissipating section)
9. Ninth Embodiment (an example in which the semiconductor package having the shield layer formed on the circuit formation surface is mounted on a substrate fitted with connectors)
10. Examples of Application to Mobile Objects

### 1. First Embodiment

### Configuration Example of Semiconductor Package

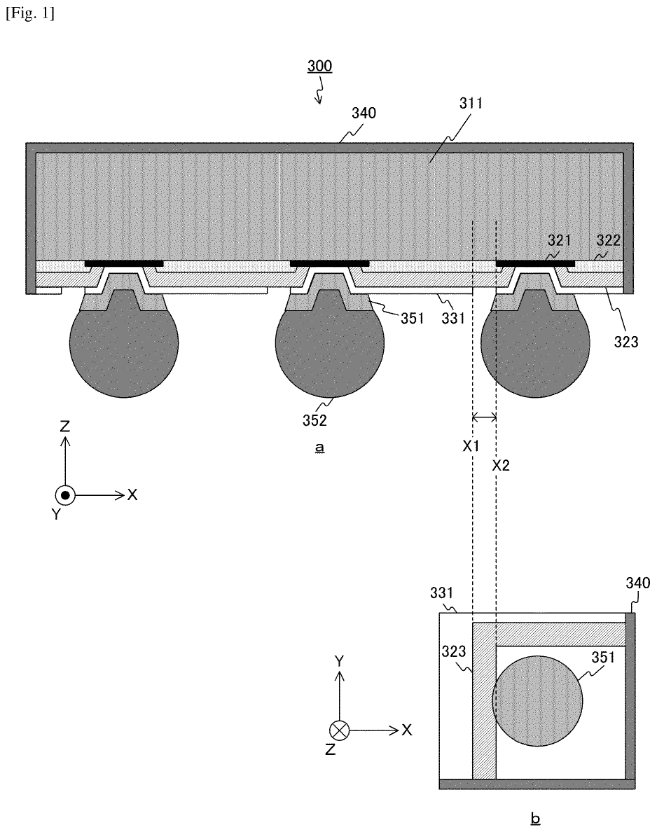

FIG. 1 includes a cross sectional view and a bottom view depicting a configuration example of a semiconductor package 300 as a first embodiment of the present technology. View “a” in FIG. 1 is a cross sectional view of the semiconductor package 300, and View “b” in FIG. 1 is a partial bottom view of the semiconductor package 300.

The semiconductor package 300 is a CSP (Chip Size Package) that includes a semi-conductor chip 311. One of the two surfaces of the semiconductor chip 311 has circuits such as an IC (Integrated Circuit) formed thereon. That surface is referred to as the “circuit formation surface” or the “surface” hereunder. Further, the direction from the surface to the back relative thereto is referred to as the “upward” direction. Further, the axis perpendicular to the surface of the semiconductor chip 311 is referred to as a “Z axis,” and the direction parallel to the surface as an “X axis.” The axis perpendicular to both the X axis and the Z axis is referred to as a “Y axis.” View “a” in FIG. 1 is a cross sectional view as viewed from the Y axis direction.

A predetermined number of pads 321 are formed on the circuit formation surface (surface) of the semiconductor chip 311. The surface is covered with a passivation layer 322 with openings to let each of the pads 321 be exposed. The bottom surface of the passivation layer 322 is covered with an insulating layer 323 with openings to let each of the pads 321 be partially exposed.

Each of the pads 321 and the bottom surface of the insulating layer 323 are covered with a shield layer 331. Further, on the bottom surface of the shield layer 331, an under-bump metal 351 is formed in a position corresponding to each of the pads 321. A solder ball 352 is connected to each of the under-bump metals 351.

Further, the semiconductor chip 311 has its side and back surfaces, which amount to five surfaces, covered with a shield layer 340. With the shield layer 331 covering the circuit formation surface (surface) of the semiconductor chip 311 and with the shield layer 340 covering the side and back surfaces thereof, the resistance to EMI is made greater than if only the side and back surfaces of the semiconductor chip 311 are covered. Incidentally, the shield layer 340 is an example of the first shield layer described in the appended claims, and the shield layer 331 is an example of the second shield layer also described in the appended claims.

View “b” in FIG. 1 depicts regions around one under-bump metal 351 on the bottom surface of the semiconductor package 300 prior to the formation of the solder balls 352 thereon. As illustrated in View “b,” the insulating layer 323 is covered except with the shield layer 331 for some regions around the under-bump metals 351 as viewed from the Z axis direction. A region hatched with oblique lines denotes the region where the shield layer 331 is not formed, exposing the insulating layer 323. The exposed insulating layer 323 insulates the under-bump metal 351 and the solder ball 352 from their surroundings. With X2 assumed to represent the edge of the under-bump metal 351, the insulating layer 323 is exposed ranging from coordinate X1 to coordinate X2 . A distance between coordinates X1 and X2 denotes a width of the exposed region (in other words, the distance represents a spacing between the under-bump metal 351 and the shield layer 331). The spacing is set to at least 5 micrometers (μm), for example.

In View “b” in FIG. 1, the insulating layer 323 is exposed along multiple linear paths as viewed from the Z axis direction.

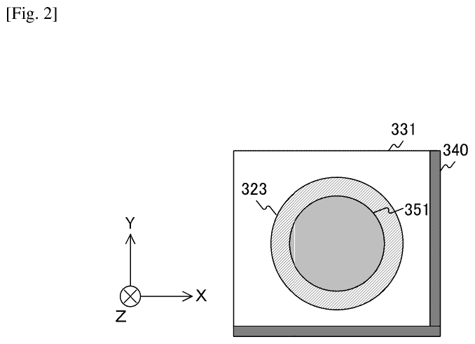

Incidentally, as depicted in FIG. 2, the insulating layer 323 may be exposed along a circular path encircling the outer circumference of the under-bump metal 351.

### Semiconductor Package Manufacturing Method

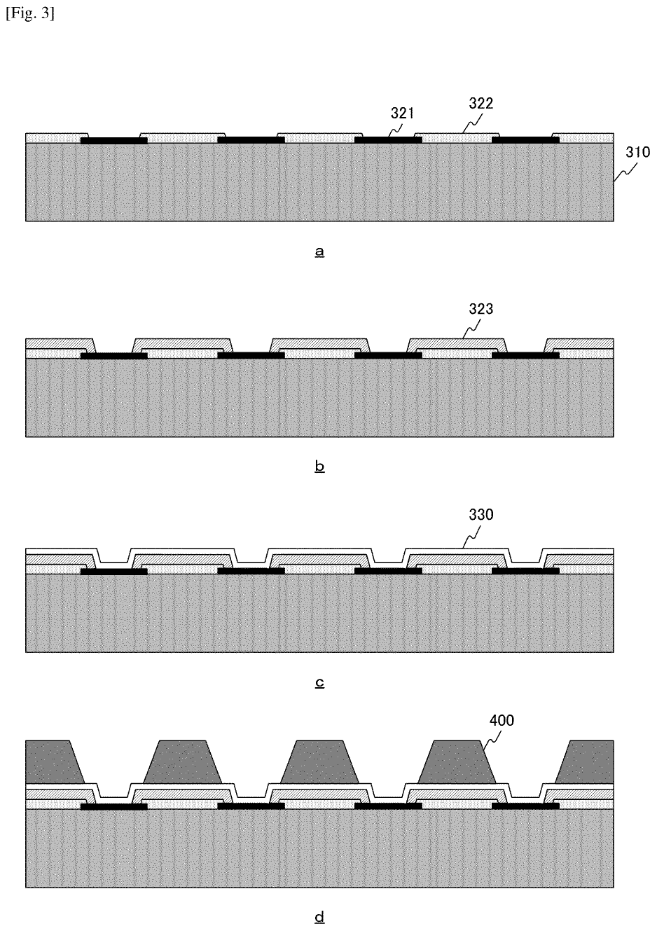

A method of manufacturing the semiconductor package 300 is explained below with reference to FIGS. 3 through 5. FIG. 3 explains a set of views of steps up to the application of a resist in the first embodiment of the present technology. First, as depicted in View “a” in FIG. 3, the pads 321 including an Al-based metal such as aluminum (Al), aluminum-neodymium (Al—Nd) alloy, or aluminum-titanium (Al—Ti) alloy are formed on the surface of a wafer 310. The surface of the wafer 310 is then covered with the passivation layer 322 with openings to let the pads 321 be partially exposed. The passivation layer 322 is configured with silicon dioxide (SiO2), silicon nitride (SiN), or TEOS (TetraEthyl OrthoSilicate), for example.

Next, as depicted in View “b” in FIG. 3, the insulating layer 323 including polyimide (PI), benzocyclobutene (BCB), or polybenzoxazole (PBO) for example, is formed by use of exposing and developing techniques.

Next, as depicted in View “c” in FIG. 3, a seed layer 330 serving as a plating seed is depicted on approximately the entire surface of the wafer 310 with the pads 321 and insulating layer 323 formed thereon, by use of a vapor deposition method, a sputtering method, a CVD (Chemical Vapor Deposition) method, or an electroless plating method.

The seed layer 330 is configured in a multilayer structure in which a chromium (Cr) or a titanium (Tr) layer approximately 1,300 angstroms thick and a copper (Cu) layer approximately 5,000 angstroms thick are stacked one on top of another by the sputtering method. Incidentally, the chromium (Cr) or the titanium (Ti) layer may be replaced with a multilayer structure in which a nickel (Ni), a palladium (Pd), or a platinum (Pt) layer and a copper (Cu) layer are stacked one on top of another. As another alternative, there may be provided a three-layer structure in which nickel (Ni), palladium (Pd), or platinum (Pt) layer; titanium (Ti) or chromium (Cr) layer; and copper (Cu) layer are stacked one on top of another.

Next, as depicted in View “d” in FIG. 3, a resist 400 is applied onto the seed layer 330. Electroplating or electroless plating is carried out with the resist 400 used as a mask.

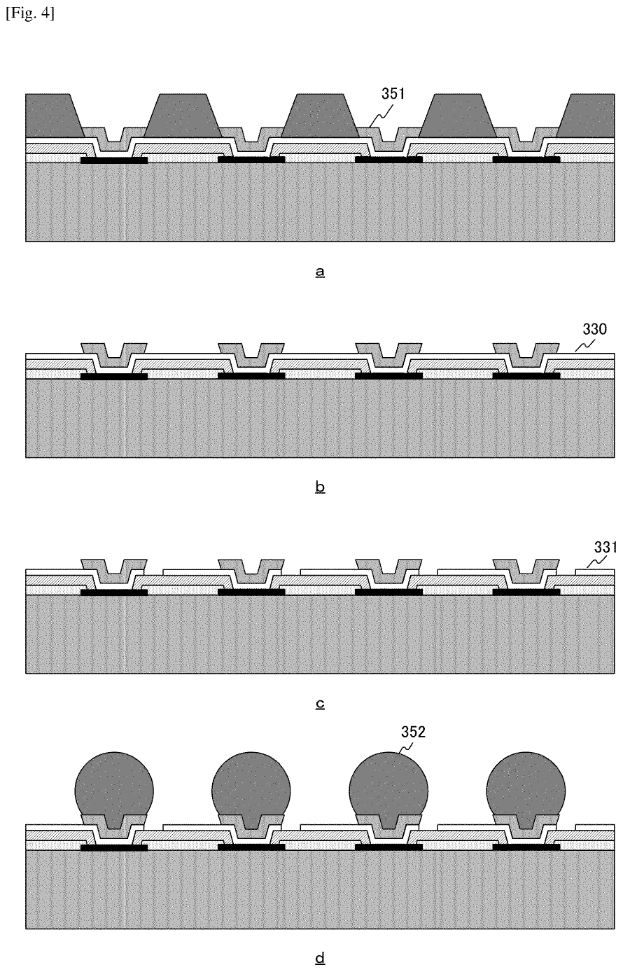

FIG. 4 explains a set of views of steps up to the formation of the solder balls 352 in the first embodiment of the present technology. As depicted in View “a” in FIG. 4, the under-bump metals 351 are formed by plating. A possible material of the under-bump metals 351 may be copper (Cu), with nickel (Ni) used as a barrier metal, for example.

Next, as depicted in View “b” in FIG. 4, the resist 400 is removed. As illustrated in View “c” in FIG. 4, the seed layer 330 is then removed by etching, leaving portions thereof that function as the shield layer 331. The shield layer 331 on the circuit formation surface of the semiconductor package 300 may alternatively be formed by aluminum wiring, copper rewiring, or under-bump metals, besides the above-mentioned seed layer 330. The area ratio of the shield layer 331, with the wiring and the pads 321 included, should preferably be at least 50% of the chip area.

Next, as depicted in View “d” in FIG. 4, the solder balls 352 are mounted. They are reflowed to form bumps.

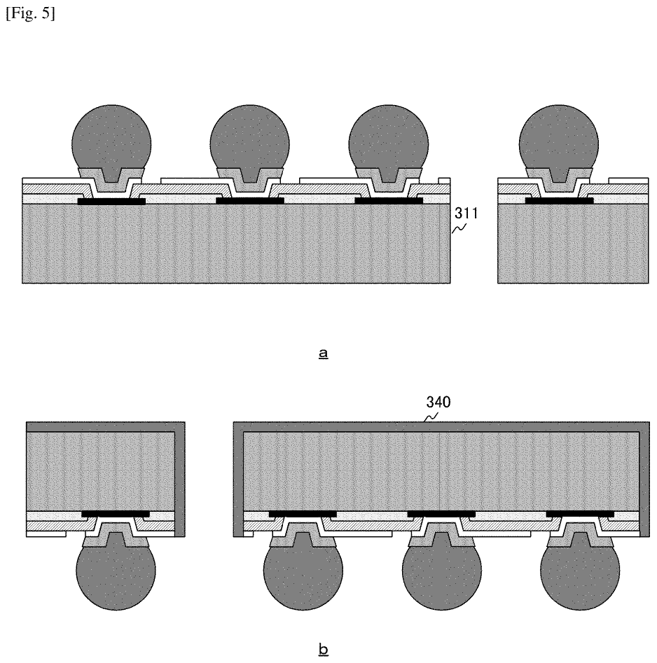

FIG. 5 explains a set of views of steps up to the formation of the shield layer 340 on the back and side surfaces of the first embodiment of the present technology. As depicted in View “a” in FIG. 5, dicing is carried out in a dicing area, cutting the wafer 310 into pieces. The individuation provides multiple semiconductor chips 311.

Next, as depicted in View “b” in FIG. 5, the shield layer 340 is formed on five surfaces of the semiconductor chip 311 except for its circuit formation surface. The shield layer 340 is a multilayer film deposited by using at least one of such metals as copper, titanium, nickel, and gold, to a thickness of at least several micrometers (um). The shield layer 340 is formed, for example, by the sputtering method, an ion plating method, a spray coating method, the CVD method, an ink-jet method, or a screen printing method. Alternatively, the shield layer 340 may be formed by vacuum lamination in which, in a vacuum atmosphere, a metal film having the above-mentioned multilayer film is bonded to the back and side surfaces of the semi-conductor chip 311. In such a manner, a total of six surfaces including the back and side surfaces of the semiconductor chip 311 including its circuit formation surface (surface) are covered with the shield layers 331 and 340.

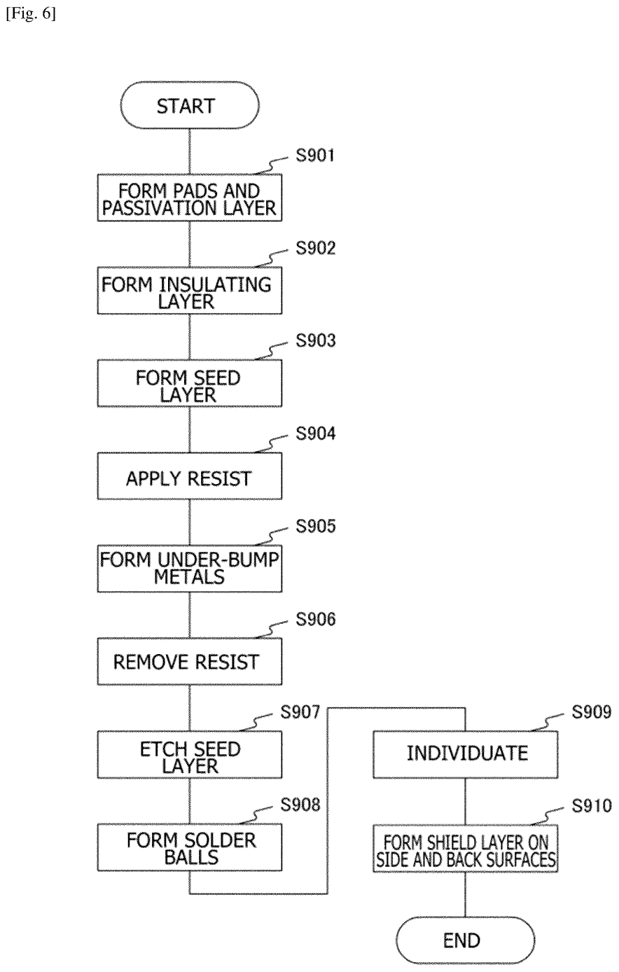

FIG. 6 is an exemplary flowchart describing an exemplary method of manufacturing the semiconductor package 300 as the first embodiment of the present technology. The manufacturing system forms the pads 321 on the wafer 310 and forms the passivation layer 322 in a manner partially exposing the pads 321 (step S901). The manufacturing system then forms the insulating layer 323 (step S902), and forms the seed layer 330 (step S903). The manufacturing system applies the resist 400 (step S904) and forms the under-bump metals 351 by plating (step S905).

The manufacturing system proceeds to remove the resist 400 (step S906) and etch the seed layer 330 to make portions thereof into the shield layer 331 (step S907). The manufacturing system then forms the solder balls 352 (step S908) before individuation (step S909). The manufacturing system then forms the shield layer 340 on the side and back surfaces of the semiconductor chip 311 (step S910). This completes the manufacturing process of the semiconductor package 300.

According to the first embodiment of the present technology, as discussed above, the back and side surfaces of the semiconductor chip 311 are covered by the shield layer 340, with the shield layer 331 also covering the circuit formation surface (surface).

This makes the resistance to EMI higher than if only the back and side surfaces are covered by the shield layer 340.

### 2. Second Embodiment

In the above-described first embodiment, portions of the seed layer 330 are used as the shield layer 331. Alternatively, portions other than the seed layer 330 may be arranged to function as a shield layer. The semiconductor package 300 as a second embodiment of the present technology differs from the first embodiment in that a rewiring layer (RDL: ReDistribution Layer) is used as the shield layer.

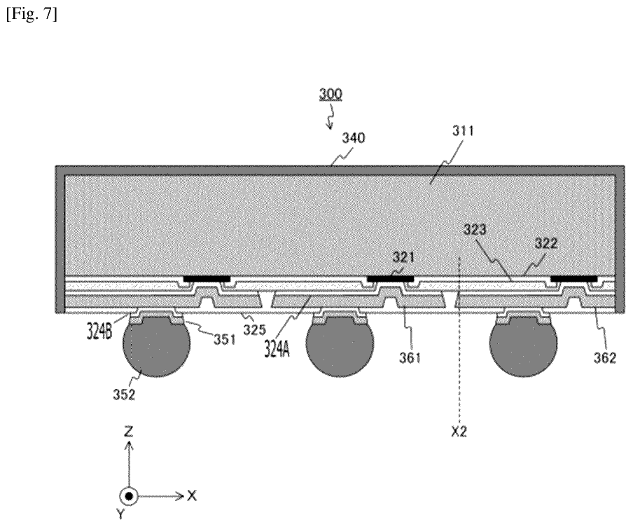

FIG. 7 is a cross sectional view depicting a configuration example of the semi-conductor package 300 as the second embodiment of the present technology. The semiconductor package 300 as the second embodiment is different from the first embodiment in that the RDL is used as a shield layer 362.

In the second embodiment, the circuit formation surface is also covered with the passivation layer 322 in a manner exposing the pads 321. The bottom surface of the passivation layer 322 is covered with a seed layer 324A. The seed layer 324A does not function as a shield. A predetermined number of under-bump metals 351 are formed on a seed layer 324B. The solder ball 352 is formed on each of the under-bump metals 351

Further, the RDLs 361 and 362 are formed on the bottom surface of the seed layer 324A. The RDL 361 is formed linearly to connect electrically with the pads 321. The other RDL 362 is formed solid as viewed from the Z axis direction and connected to ground. The RDL 362 functions as the shield layer. In FIG. 7, the RDL 362 is formed in a region on the right of coordinate X2 and the RDL 361 is wired on the left thereof.

Further, the bottom surfaces of the RDL 361, the RDL 362, and the insulating layer 323 are covered with an insulating layer 325.

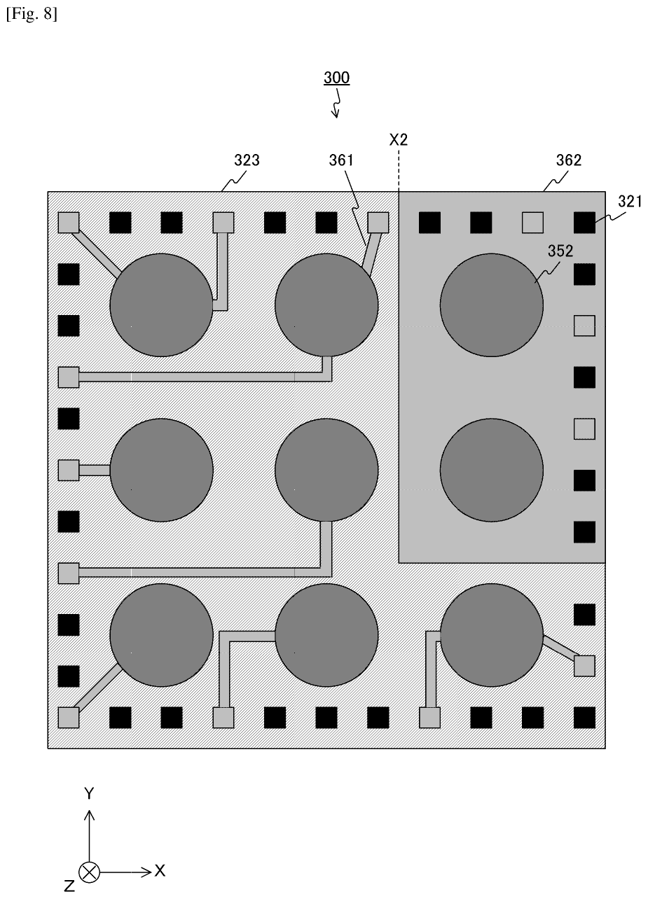

FIG. 8 is an exemplary bottom view of the semiconductor package 300 as the second embodiment of the present technology. FIG. 8 is a typical bottom view depicting the semiconductor package 300 in a state in which the insulating layer 325 located under the insulating layer 323 and the shield layer 340 on the side surface have yet to be formed.

As depicted in FIG. 8, partial regions of the bottom surface of the insulating layer 323 are covered with the RDL 362, the covered regions being used as the shield layer. The RDL 362 is further connected to ground by way of the solder balls 352. The regions covered with RDL 362 are referred to as “shielding regions.” The circuits to be shielded are disposed on top of the shielding regions.

Of the regions on the bottom surface of the insulating layer 323, those other than the shielding regions are wired with the linear RDL 361. The RDL 361 is wired between the solder ball 352 and the pad 321, for example, to provide electrical connection therebetween.

Incidentally, portions of the seed layer 330 are used as the shield layer 331 in the first embodiment, and the RDL 362 is used as the shield layer in the second embodiment. Still, these configurations are not limitative of the present technology. For example, the aluminum (Al) wiring layer or the under-bump metals of the semiconductor chip 311 may also be used as a shield layer.

According to the second embodiment of the present technology, as discussed above, portions of the RDL 362 are used as the shield layer, so that only the shielding regions of the bottom surface may be covered with the shield layer to protect circuitry.

### 3. Third Embodiment

Whereas the six surfaces of the semiconductor package 300 are covered with the shield layers in the first embodiment, the semiconductor package 300 may be placed in a semiconductor module. This third embodiment differs from the first embodiment in that the semiconductor package 300 of the first embodiment is installed in a semi-conductor module.

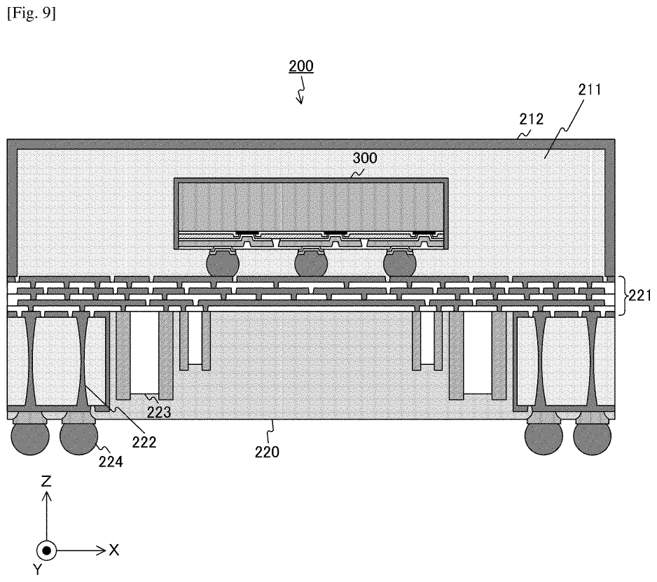

FIG. 9 is a cross sectional view depicting a configuration example of a semi-conductor module 200 as the third embodiment of the present technology. The semi-conductor module 200 as the third embodiment includes a frame substrate 220 and a semiconductor package 300. Incidentally, the frame substrate 220 is an example of the substrate described in the appended claims.

One of the two surfaces of the frame substrate 220, which is regarded as the top surface, has a wiring layer 221 formed thereon and is provided with the circuit formation surface of the semiconductor package 300 in the first embodiment. Further, the wiring layer 221 and the semiconductor package 300 are covered with a mold resin 211. The side and top surfaces of the mold resin 211 are covered with a shield layer 212.

Further, in the frame substrate 220, a predetermined number of passive components 223 are mounted and a predetermined number of through vias 222 are formed. A pre-determined number of solder balls 224 are formed on the bottom surface of the frame substrate 220. The solder balls 224 are connected to the wiring layer 221 by way of the through vias 222.

As discussed above, the six surfaces of the semiconductor package 300 are covered with the shield layers 331 and 340. This prevents the electrical characteristics of the semiconductor module module 200 from being degraded due to EMI from the set (not depicted) in which the semiconductor module 200 is mounted.

Incidentally, the second embodiment may be applied to the third embodiment.

According to the third embodiment of the present technology, as discussed above, the semiconductor package 300 covered with the shield layers is mounted in the semi-conductor module 200. This improves the resistance of the semiconductor module 200 to EMI.

### 4. Fourth Embodiment

In the above-described third embodiment, the through vias 222 are formed in the frame substrate 220. In this configuration, however, EMI can degrade the electrical characteristics of the circuits connected with the through vias 222. The semiconductor module 200 as a fourth embodiment differs from the third embodiment in that the through vias are coaxially structured.

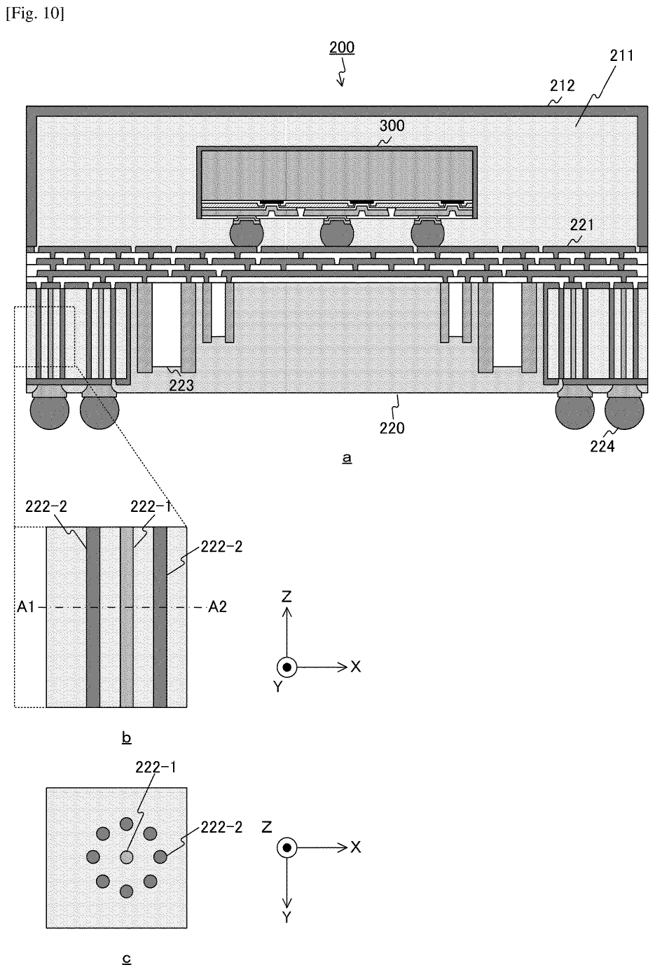

FIG. 10 is a cross sectional view depicting a configuration example of the semi-conductor module 200 as the fourth embodiment of the present technology. View “a” in FIG. 10 is an exemplary cross sectional view of the semiconductor module 200 as viewed from the Y axis direction.

View “b” in FIG. 10 is an enlarged view of the portion encircled by dotted lines of “a” in the illustration. As depicted in View “b” in FIG. 10, the fourth embodiment has signal vias 222-1 and ground vias 222-2 formed in the frame substrate 220. The signal vias 222-1 penetrate the frame substrate 220 to transmit electrical signals. The ground vias 222-2 penetrate the frame substrate 220 to be connected to ground.

View “c” in FIG. 10 is a cross sectional view taken on a line segment A1-A2 in View “b” in the illustration as viewed from the Z axis direction. As depicted in View “c” in FIG. 10, multiple ground vias 222-2 surround each signal via 222-1. The through vias, coaxially structured as mentioned above, inhibit the electrical characteristics of the semiconductor module 200 from being degraded due to EMI from the set (not depicted) in which the semiconductor module 200 is mounted.

Incidentally, the second embodiment may be applied to the fourth embodiment.

According to the fourth embodiment of the present technology, as discussed above, the through vias are coaxially structured to improve the resistance of the semi-conductor module 200 to EMI.

### 5. Fifth Embodiment

In the above-described third embodiment, there is no circuit that can become a noise source inside the semiconductor module 200. However, such circuits may be provided as needed. The semiconductor module 200 as a fifth embodiment differs from the third embodiment in that a circuit as a noise source is disposed inside the module.

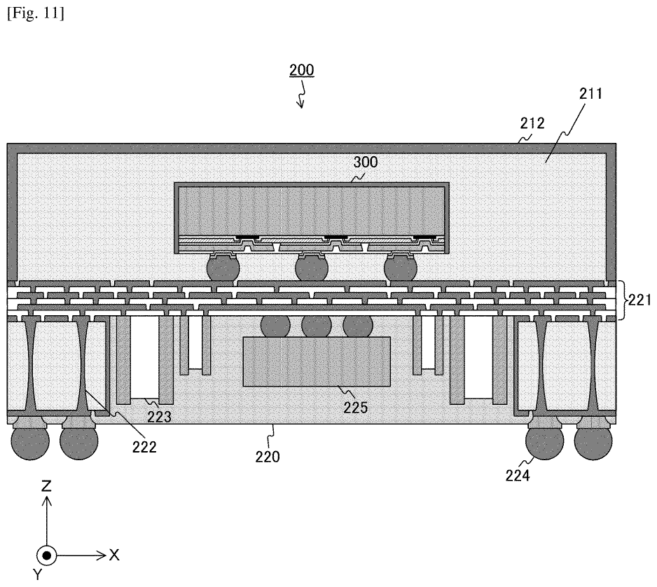

FIG. 11 is a cross sectional view depicting a configuration example of the semi-conductor module 200 as the fifth embodiment of the present technology. The semi-conductor module 200 as the fifth embodiment differs from the third embodiment in that a digital circuit 225 is additionally provided.

The digital circuit 225 is mounted in the frame substrate 220 below the wiring layer 221. The digital circuit 225 generates noise and may presumably be PMICs (Power Management ICs), for example.

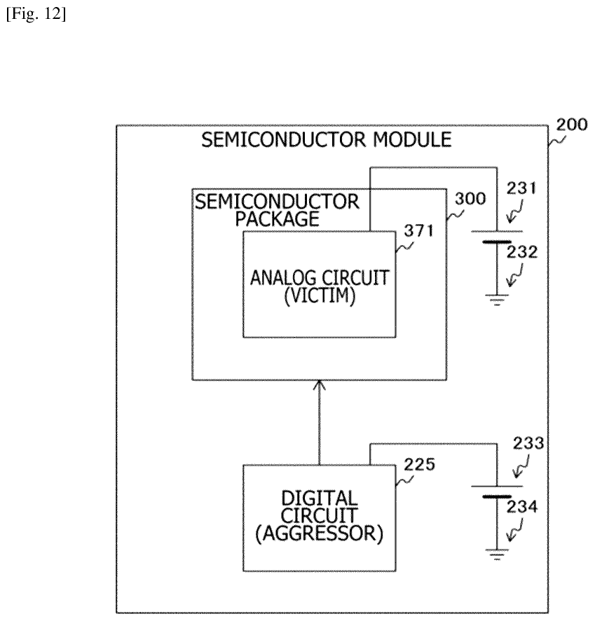

FIG. 12 is a block diagram depicting a configuration example of the semiconductor module 200 as the fifth embodiment of the present technology. The semiconductor module 200 includes the semiconductor package 300 and the digital circuit 225. An analog circuit 371 is disposed inside the semiconductor package 300. The analog circuit 371 may presumably be RFICs (Radio-Frequency ICs), for example.

Also, the analog circuit 371 is connected to a power supply 231 and a ground 232. On the other hand, the digital circuit 225 is connected to a power supply 233 and a ground 234. As mentioned above, the digital circuit 225 can be a noise source. Further, the analog circuit 371 is assumed to be vulnerable to noise from the digital circuit 225. In this case, the digital circuit 225 is an aggressor and the analog circuit 371 is a victim. Incidentally, the analog circuit 371 is an example of the first circuit described in the appended claims, and the digital circuit 225 is an example of the second circuit also described in the appended claims.

As depicted in FIG. 12, the power supply and the ground of the analog circuit 371 (victim) are different from those of the digital circuit 225 (aggressor) and are thus separated from the latter. This prevents the victim from being affected by electro-magnetic noise overlaid with the power source and the ground of the aggressor, thereby inhibiting the electrical characteristics of the victim from being degraded.

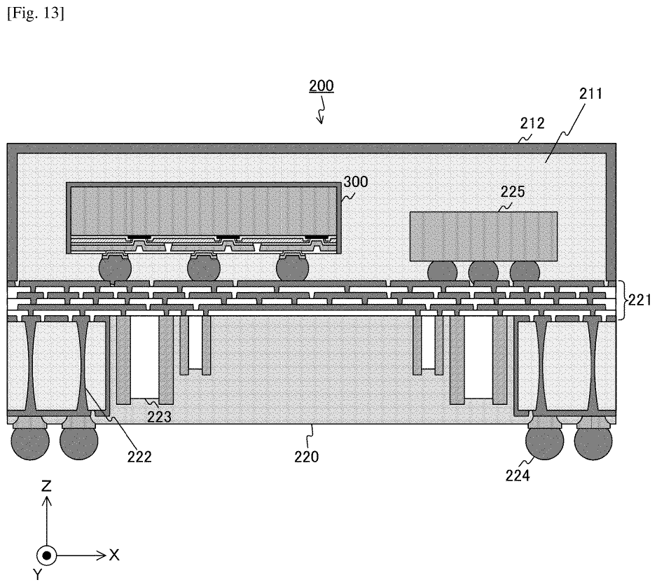

Incidentally, as depicted in FIG. 13, the digital circuit 225 may be mounted together with the semiconductor package 300 on the top surface of the frame substrate 220.

Preferably, the second or the fourth embodiment may be applied to the fifth embodiment.

According to the fifth embodiment of the present technology, as discussed above, the power supply and the ground of the analog circuit 371 (victim) are separated from the digital circuit 225. This inhibits the electrical characteristics of the victim from being degraded even when the aggressor is placed inside the module.

### 6. Sixth Embodiment

In the above-described fifth embodiment, the digital circuit 225 acting as a noise source is disposed inside the semiconductor module 200. However, the shield layer of the semiconductor module 200 may not be sufficient as a countermeasure against EMI. The semiconductor module 200 as a sixth embodiment differs from the fifth embodiment in that the semiconductor package 300 is surrounded by a shield.

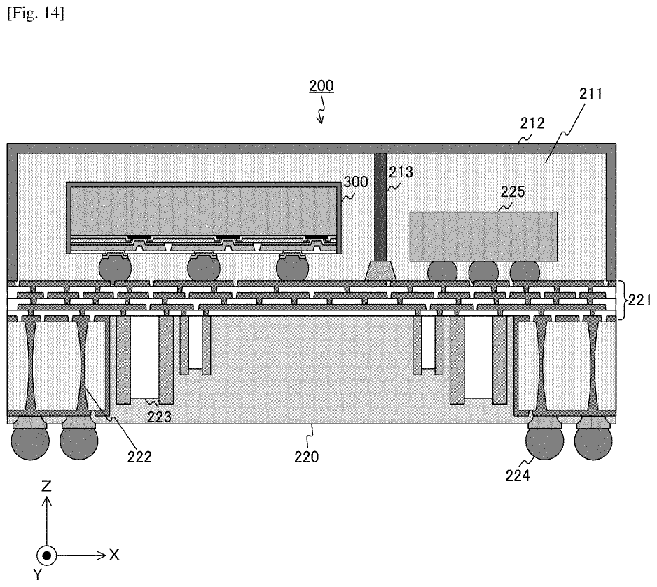

FIG. 14 is a cross sectional view depicting a configuration example of the semi-conductor module 200 as the sixth embodiment of the present technology. The semi-conductor module 200 as the sixth embodiment is different from the fifth embodiment in that a shield 213 is disposed on the top surface of the frame substrate 220. Also, in the sixth embodiment, the digital circuit 225 along with the semiconductor package 300 is mounted on the top surface of the frame substrate 220.

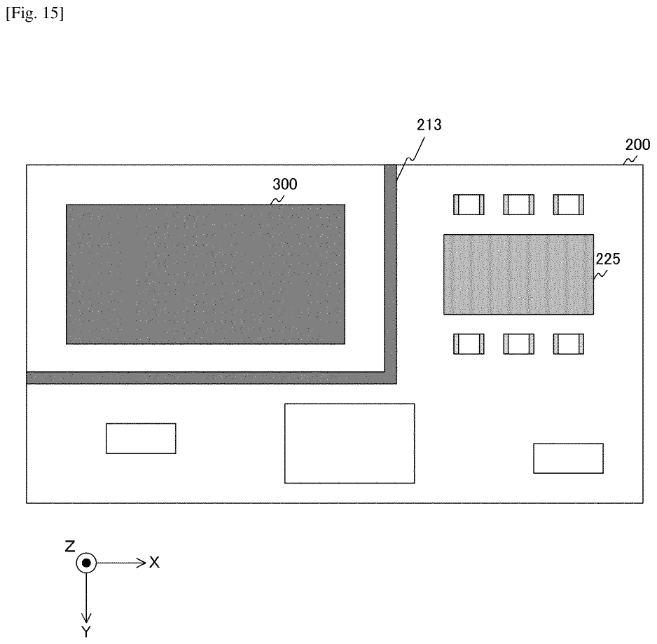

FIG. 15 is an exemplary top view of the semiconductor module 200 as the sixth embodiment of the present technology. FIG. 15 is a top view of the semiconductor module 200 in a state in which the mold resin 211 and the shield layer 212 have yet to be formed. The shield 213 is disposed around the semiconductor package 300 as viewed from the Z axis direction. In other words, the semiconductor package 300 is mounted in a region segmented by the shield 213. Disposing the shield 213 in this manner makes it possible to prevent the electrical characteristics of the circuits in the semiconductor package 300 from being degraded by EMI from the digital circuit 225 (aggressor).

Incidentally, the second or the fourth embodiment may be applied to the sixth embodiment.

According to the sixth embodiment of the present technology, as discussed above, the semiconductor package 300 is mounted in the region segmented by the shield 213. This further improves the resistance to EMI.

### 7. Seventh Embodiment

Whereas the six surfaces of the semiconductor package 300 are covered with the shield layers in the above-described first embodiment, the semiconductor package 300 may be placed in an electronic device. This seventh embodiment differs from the first embodiment in that the semiconductor package 300 of the first embodiment is incorporated in an electronic device.

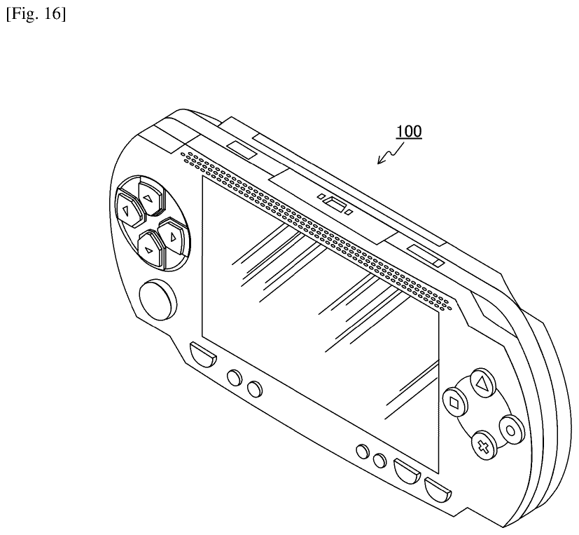

FIG. 16 is an exemplary perspective view of an electronic device 100 as the seventh embodiment of the present technology. The electronic device 100 may be used as a game machine, for example.

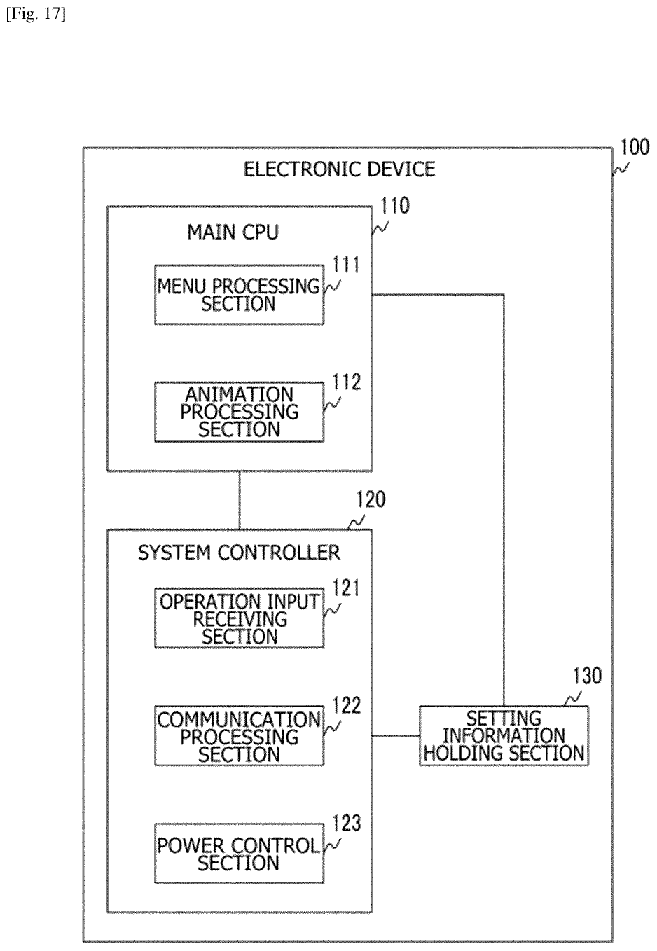

FIG. 17 is a block diagram depicting a configuration example of the electronic device 100 as the seventh embodiment of the present technology. The electronic device 100 includes a main CPU (Central Processing Unit) 110 and a system controller 120. The main CPU 110 and the system controller 120 are powered by batteries or other sources, not depicted, in different power supply systems. The main CPU 110 includes a menu processing section 111 and an application processing section 112, the menu processing section 111 generating a menu screen allowing a user to set various information or to select applications, the application processing section 112 executing the applications.

The electronic device 100 also includes a setting information holding section 130 such as a memory that holds various information set by the user. The user-set information is output to the setting information holding section 130 from the main CPU 110. The setting information holding section 130 holds the information thus output. The system controller 120 includes an operation input receiving section 121, a communication processing section 122, and a power control section 123. The operation input receiving section 121 detects the states of operation keys. Further, the communication processing section 122 processes communications with an external device. The power control section 123 controls the power being supplied to the components of the electronic device 100. Incidentally, the semiconductor package 300 of the first embodiment or the semiconductor module 200 of the third embodiment is incorporated in at least one of the components including the main CPU 110, system controller 120, and setting information holding section 130.

The semiconductor package 300 of the first embodiment or the semiconductor module 200 of the third embodiment may be used to prevent the electrical characteristics of the electronic device 100 from being degraded by EMI.

Incidentally, the second, the fourth, the fifth, or the sixth embodiment may be applied to the seventh embodiment.

According to the seventh embodiment of the present technology, as discussed above, the semiconductor package 300 or the semiconductor module 200 is incorporated in the electronic device 100. This improve the resistance of the electronic device 100 to EMI.

### 8. Eighth Embodiment

Whereas the six surfaces of the semiconductor package 300 in the above-described first embodiment are covered with shield layers, the semiconductor package 300, when mounted on the frame substrate, may cause problems of heat dissipation performance. An eighth embodiment differs from the first embodiment in that the semiconductor package 300 of the first embodiment is mounted on a substrate arranged to promote heat dissipation.

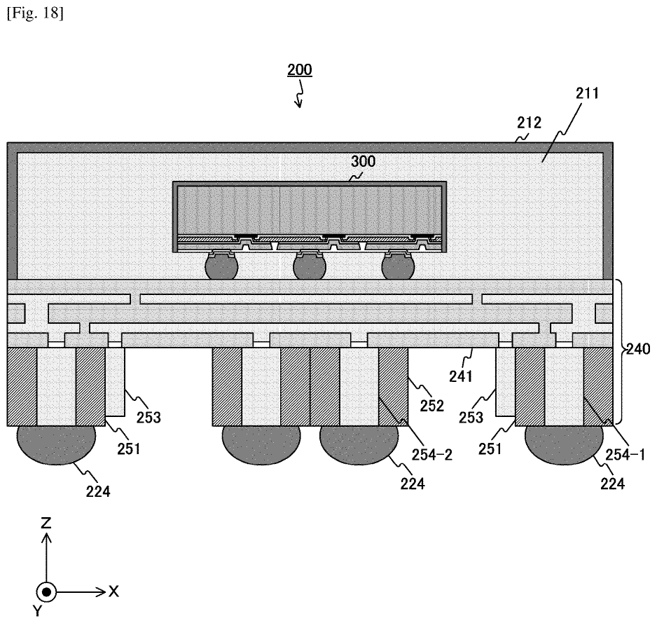

FIG. 18 is a cross sectional view depicting a configuration example of the semi-conductor module 200 as the eighth embodiment of the present technology. The semi-conductor module 200 as the eighth embodiment includes a substrate 240 and the semiconductor package 300.

The substrate 240 includes a wiring layer 241, a projecting section 251, and a heat dissipating section 252. The semiconductor package 300 is mounted on the top surface of the wiring layer 241. Further, the wiring layer 241 and the semiconductor package 300 are covered with the mold resin 211. The side and top surfaces of the mold resin 211 are covered with the shield layer 212. Further, the projecting section 251 and the heat dissipating section 252 are provided on the bottom surface of the wiring layer 241.

The projecting section 251 is a member that projects from the bottom surface of the wiring layer 241 in the Z axis direction. When viewed from the Z axis direction, the projecting section 251 extends linearly along at least part of the outer circumference of the substrate 240. The inner walls of the projecting section 251 are covered with a metallic film 253. The metallic film 253 functions as a shield layer. The heat dissipating section 252 is a member that dissipates heat and is positioned on the bottom surface of the wiring layer 241 in a manner corresponding to the position where the semiconductor package 300 is mounted on the top surface of the wiring layer 241. For example, in the case where the semiconductor package 300 is mounted in the middle of the top surface of the wiring layer 241, the heat dissipating section 252 is provided in the middle of the bottom surface of the wiring layer 241.

Further, the projecting section 251 and the heat dissipating section 252 are each provided with conductive vias penetrating the projecting section 251 or the heat dissipating section 252 in the Z axis direction. The projecting section 251 has signal vias 254-1 as its conductive vias, and the heat dissipating section 252 has ground vias 254-2 as its conductive vias. One end of each of the conductive vias is connected to the wiring layer 241 and the other end is connected to the solder ball 224. The signal vias 254-1 transmit electrical signals. The ground vias 254-2 are connected to ground potential.

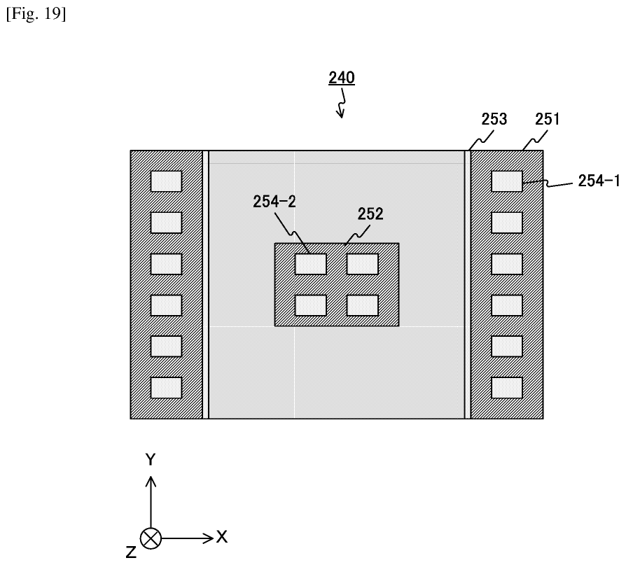

FIG. 19 is an exemplary bottom view of the substrate 240 in the eighth embodiment of the present technology. FIG. 19 is a bottom view of the substrate 240 in a state in which the solder balls 224 have yet to be mounted. The projecting sections 251 are provided on the right and left edges of the substrate 240. These projecting sections 251 have a predetermined number of signal vias 254-1 arrayed therein. Incidentally, the shape of the projecting section 251 is not limited to what is depicted in FIG. 19; the projecting section 251 may alternatively have a frame-like shape as viewed from the Z axis direction.

Further, the island-like heat dissipating section 252 is disposed in the middle of the bottom surface of the substrate 240. A predetermined number of ground vias 254-2 are provided in the heat dissipating section 252. These ground vias 254-2 efficiently dissipate the heat generated by the semiconductor package 300, thereby improving the heat dissipation performance.

Further, in a space between the projecting section 251 and the heat dissipating section 252, a semiconductor chip and circuits may be mounted, as will be described later.

According to the eighth embodiment of the present technology, as discussed above, the semiconductor package 300 is mounted on the substrate 240 having the heat dissipating section 252. This enhances the heat dissipation performance.

### First Modification

Whereas the semiconductor package 300 is mounted on the substrate 240 in the above-described eighth embodiment, disposing a noise source or a circuit vulnerable to noise on the bottom surface of the substrate 240 can degrade the electrical characteristics of the semiconductor module 200 due to noise. The semiconductor module 200 as a first modification of the eighth embodiment differs from the eighth embodiment in that ground vias are disposed around the noise source or the circuit vulnerable to noise.

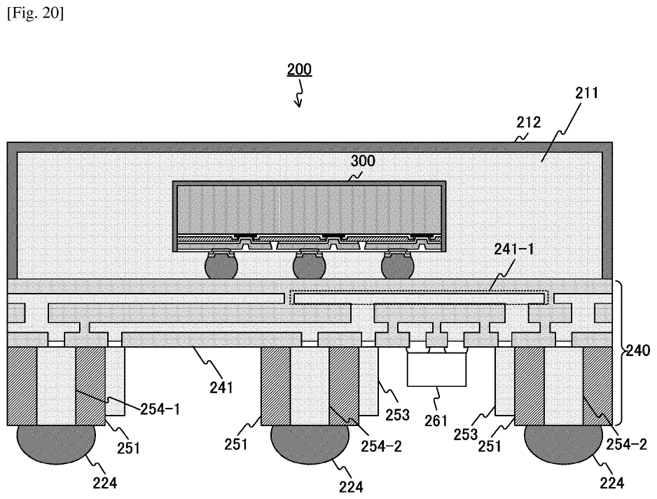

FIG. 20 is a cross sectional view depicting a configuration example of the semi-conductor module 200 as the first modification of the eighth embodiment of the present technology. The semiconductor module 200 as the first modification of the eighth embodiment is different from the eighth embodiment in that the heat dissipating section 252 is not provided and that an integrated circuit 261 is mounted on the bottom surface of the wiring layer 241. The integrated circuit 261 is a potential noise source or a circuit vulnerable to noise. For example, RFICs (Radio Frequency Integrated Circuits) or a transmitting-side IC may be mounted as the integrated circuit 261.

Further, part of the projecting section 251 surrounds the integrated circuit 261. The metallic film 253 is formed on the inner walls of that part of the projecting section 251. Further, on the wiring layer 241, rewiring 241-1 connected to ground is provided on top of the integrated circuit 261. The rewiring 241-1 should preferably cover the top surface of the integrated circuit 261 as viewed from the Z axis direction. The rewiring 241-1 includes a material such as silicon-aluminum (Si—Al) alloy or copper (Cu). The metallic film 253 and the rewiring 241-1 function as shield layers that shield from noise. Incidentally, the metallic film 253 is an example of the first shield layer described in the appended claims, and the rewiring 241-1 is an example of the second shield layer also described in the appended claims.

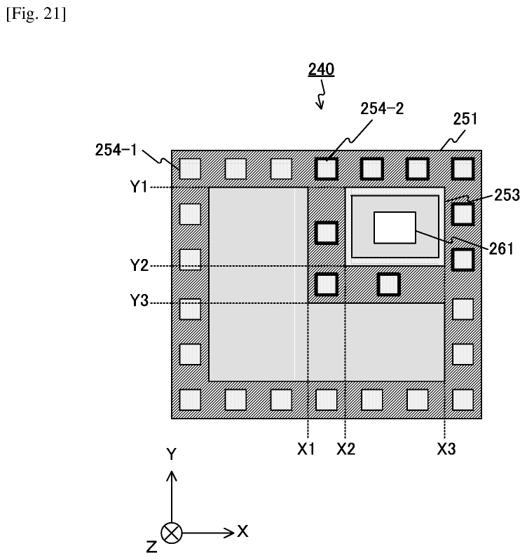

FIG. 21 is an exemplary bottom view of the substrate 240 in the first modification of the eighth embodiment of the present technology. As depicted in FIG. 21, the projecting section 251 has frame-like portions that partially branch to encircle, together with other portions of the projecting section 251, the integrated circuit 261. In FIG. 21, the region surrounded by coordinates (X1, Y1), (X1, Y3), (X2, Y1), (X2, Y2), (X3, Y2), and (X3, Y3) corresponds to the branching portions.

Further, of the portions constituting the projecting section 251, those surrounding the integrated circuit 261 have the ground vias 254-2 disposed therein. In FIG. 21, bold squares represent the ground vias 254-2. The ground vias 254-2 together with the above-mentioned electromagnetic shields (metallic film 253 and rewiring 241-1) shield from noise. This improves the electrical characteristics.

Incidentally, whereas the heat dissipating section 252 is not provided in the first modification of the eighth embodiment, the heat dissipating section 252 may be added if a space permits.

According to the first modification of the eighth embodiment of the present technology, as discussed above, the electromagnetic shield and the ground vias 254-2 are disposed in a manner surrounding the integrated circuit 261. This makes it possible to shield from noise and thereby improve the electrical characteristics.

### Second Modification

Whereas the semiconductor chip is not mounted on the bottom of the frame substrate 220 in the eighth embodiment, the semiconductor chip may be added thereto. This second modification of the eighth embodiment differs from the eight embodiment in that the semiconductor chip is mounted on the bottom of the frame substrate 220.

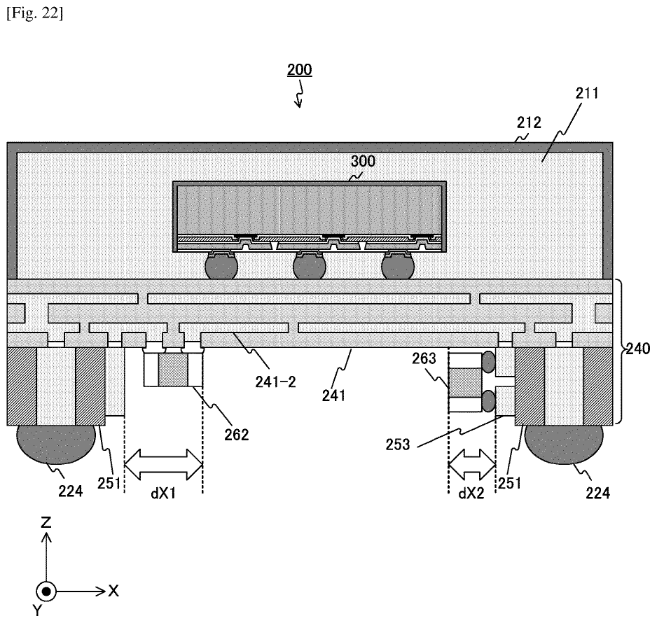

FIG. 22 is a cross sectional view depicting a configuration example of the semi-conductor module 200 as the second modification of the eighth embodiment of the present technology. The semiconductor module 200 as the second modification of the eighth embodiment is different from the eight embodiment in that the heat dissipating section 252 is not provided and that a predetermined number of semiconductor chips 262 and 263 are further mounted.

The semiconductor chip 262 is connected to rewiring 241-2 disposed on the bottom side of the wiring layer 241. The semiconductor chip 263 is connected to the inner walls of the projecting section 251 by way of the metallic film 253. This part of the metallic film 253 is used as the wiring that connects to the wiring layer 241. When connected to the inner walls, the semiconductor chip 263 is positioned closer to the conductive vias than if it is mounted on the bottom surface. This improves PI (Power Integrity).

Also, when the semiconductor chip 263 is attached to the inner walls of the projecting section 251, the distance from the inner walls to the chip edges becomes shorter than if the semiconductor chip 263 is mounted on the bottom surface. For example, a distance dX2 from the right-side inner wall to the left edge of the semi-conductor chip 263 is shorter than a distance dX1 from the left-side inner wall to the right edge of the semiconductor chip 262. This leaves a wider space in which to in-corporate other chips and circuits.

Incidentally, whereas the semiconductor chips 262 and 263 are both included, either of them may alternatively be provided. Further, the semiconductor chip 262 is an example of the second semiconductor chip described in the appended claims.

Incidentally, although the second modification of the eighth embodiment does not include the heat dissipating section 252, the heat dissipating section 252 may be additionally provided if the space permits. Further, this third modification may be applied to the second modification of the eighth embodiment.

According to the second modification of the eighth embodiment of the present technology, as discussed above, the semiconductor chips 262 and 263 are mounted on the bottom of the substrate 240. This improves the functionality of the semiconductor module 200. In particular, attaching the semiconductor chip 263 to the inner walls of the projecting section 251 enhances the PI properties.

### 9. Ninth Embodiment

In the above-described eighth embodiment, the solder balls 224 are used to connect the semiconductor module 200 to external circuits or devices. This configuration, however, makes it difficult for the semiconductor module 200 to be detached and re-connected. The semiconductor module 200 as a ninth embodiment differs from the eighth embodiment in that connectors are provided on the bottom of the substrate.

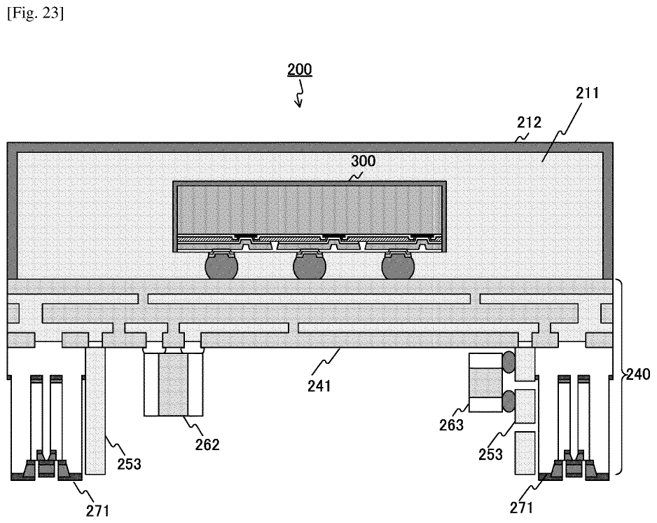

FIG. 23 is a cross sectional view depicting a configuration example of the semi-conductor module 200 as the ninth embodiment of the present technology. In the semi-conductor module 200 of the ninth embodiment, a predetermined number of connectors 271 are mounted on the bottom of the substrate 240, replacing the projecting section 251 and heat dissipating section 252 that are eliminated. The connectors 271 allow the semiconductor module 200 to be easily detached and re-connected, which improves reworkability. The ninth embodiment also provides for high-speed interfacing.

Further, the inner walls of the connectors 271 are covered with the metallic film 253. The metallic film 253 functions as a shield layer. The semiconductor chip 262 is mounted on the bottom of the substrate 240, and the semiconductor chip 263 is connected to the inner walls by way of the metallic film 253. Incidentally, although the semiconductor chips 262 and 263 are both provided, only either of them may alternatively be included. As another alternative, there may be a configuration that excludes the semiconductor chips.

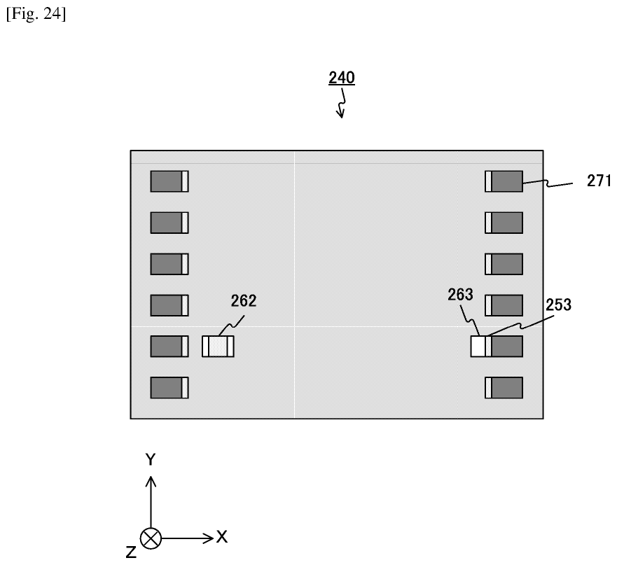

FIG. 24 is an exemplary bottom view of the substrate 240 in the ninth embodiment of the present technology. As depicted in FIG. 24, the connectors 271 may be arrayed along the left and right sides of the substrate 240. Incidentally, the connectors 271 may further be arrayed along the upper and lower sides of the substrate 240.

Incidentally, although the heat dissipating section 252 is not included in the ninth embodiment, the heat dissipating section 252 may additionally be provided if the space permits. Preferably, the first modification of the eight embodiment may be applied to the ninth embodiment.

According to the ninth embodiment of the present technology, as discussed above, the connectors 271 are mounted on the bottom of the substrate 240. This enhances the reworkability of the module.

### 10. Examples of Application to Mobile Bodies

The technology of the present disclosure (the present technology) may be applied to diverse products. For example, the technology may be implemented as an apparatus to be mounted on such mobile bodies as automobiles, electric vehicles, hybrid electric vehicles, motorcycles, bicycles, personal mobility devices, aircraft, drones, ships, and robots.

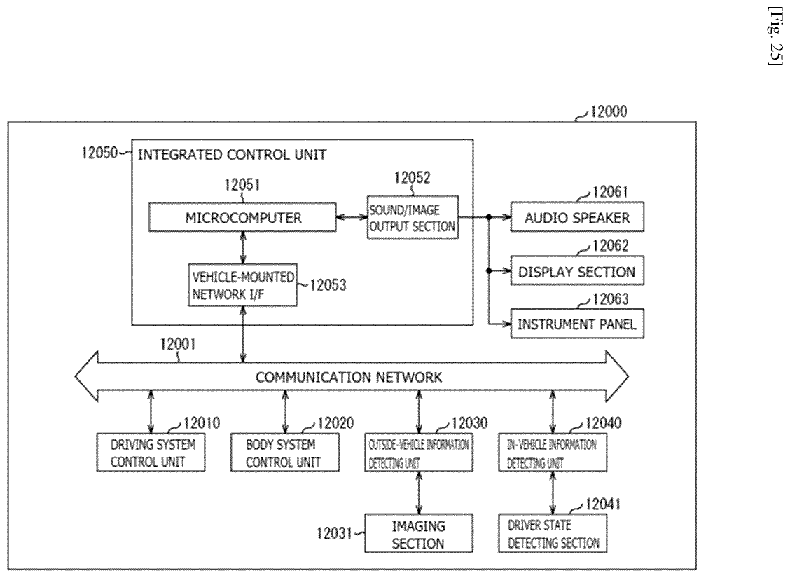

FIG. 25 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 25, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional con-figuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 25, an audio speaker 12061, a display section 12062, and an instrument panel 12063 are illustrated as the output device. The display section 12062 may, for example, include at least one of an on-board display and a head-up display.

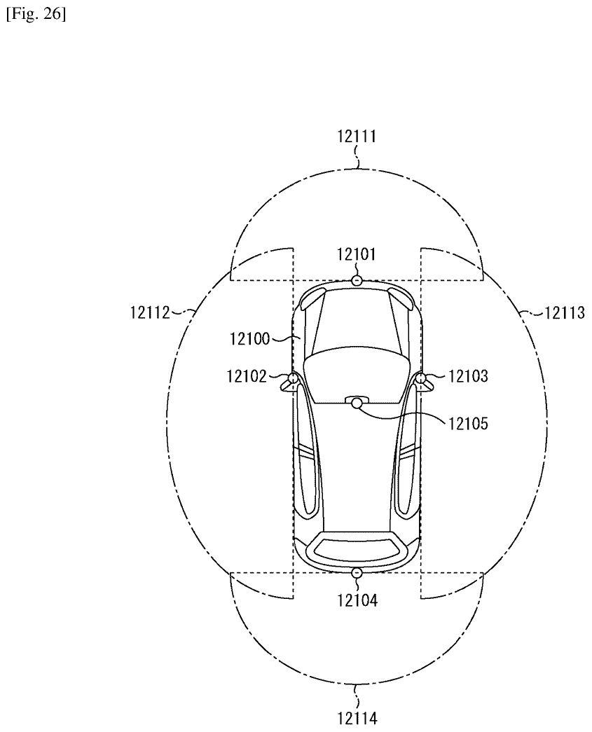

FIG. 26 is a diagram depicting an example of the installation position of the imaging section 12031.

In FIG. 26, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 26 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by super-imposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform co-operative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Described above is one example of the vehicle control system to which the technology of the embodiment of the present disclosure may be applied. This technology may be applied advantageously to the imaging section 12031 among the above-descried components, for example. Specifically, the semiconductor package 300 in FIG. 1 may be applied to the imaging section 12031. Applying the technology of the present disclosure to the imaging section 12031 makes it possible to improve the resistance to EMI and thereby enhance the reliability of the system.

Incidentally, the embodiments described above are merely examples in which the present technology may be implemented. The particulars of the embodiments correspond generally to the inventive matters claimed in the appended claims. Likewise, the inventive matters named in the appended claims correspond generally to the particulars of the embodiments with the same names in the foregoing description of the preferred embodiments of the present technology. However, these embodiments and other examples are not limitative of the present technology that may also be implemented using various modifications and alterations of the embodiments so far as they are within the scope of the appended claims.

Incidentally, the advantageous effects stated in this description are examples and not limitative of the present disclosure that may provide other advantages as well.

Incidentally, the present technology can also have the following configurations.
(1)

A semiconductor package including:
a semiconductor chip configured to have one of two surfaces thereof mounted with a circuit, the circuit formation surface constituting a circuit formation surface;
a first shield layer configured to cover a side of the semiconductor chip and the other surface thereof; and
a second shield layer configured to cover the circuit formation circuit.
(2)

The semiconductor package according to (1), further including:
an under-bump metal,
in which the second shield layer includes part of a seed layer for growing the under-bump metal.
(3)

The semiconductor package according to (2), further including:
an insulating layer configured to cover the circuit formation surface,
in which the second shield layer covers the insulating layer except for a predetermined region around the under-bump metal as viewed from a direction perpendicular to the semiconductor chip.
(4)

The semiconductor package according to (1), further including:
a first redistribution layer formed outside of a protection area as part of the circuit formation surface,
in which the second shield layer includes a second redistribution layer that covers the protection area and is connected to a ground.
(5)

A semiconductor module including:
a semiconductor package including
a first semiconductor chip configured to have one of two surfaces thereof mounted with a circuit, the circuit formation surface constituting a circuit formation surface,
a first shield layer configured to cover a side of the semiconductor chip and the other surface thereof,
and a second shield layer configured to cover the circuit formation circuit; and
a substrate configured to have the semiconductor package mounted thereon.
(6)

The semiconductor module according to (5), further including:
a signal via configured to penetrate the substrate; and
a plurality of ground vias configured to penetrate the substrate in a manner surrounding the signal via as viewed from a direction perpendicular to the substrate.
(7)

The semiconductor module according to (5) or (6), further including:
a first circuit formed in the first semiconductor chip; and
a second circuit configured to generate noise,
in which the first circuit and the second circuit are each connected to a different ground.
(8)

The semiconductor module according to (7), in which the second circuit is formed in the substrate.
(9)

The semiconductor module according to (7), in which the semiconductor package and the second circuit are disposed on a surface of the substrate.
(10)

The semiconductor module according to (9), further including: a shield configured to surround the semiconductor package as viewed from a direction perpendicular to the substrate.
(11)

The semiconductor module according to (5), in which the substrate includes a wiring layer configured to be mounted with the semiconductor package in a predetermined position on one of two surfaces of the substrate,
a projecting section configured to project in a direction perpendicular to the other surface of the substrate,
a first shield layer configured to cover an inner wall of the projecting section, and
a signal via configured to penetrate the projecting section.
(12)

The semiconductor module according to (11), in which the substrate further includes a heat dissipating section disposed in a position corresponding to the predetermined position on the other surface of the substrate, and
a ground via configured to penetrate the heat dissipating section and have ground potential.
(13)

The semiconductor module according to (11) or (12), further including:
an integrated circuit disposed on the other surface of the substrate,
in which the wiring layer includes a second shield layer, and
the integrated circuit is surrounded by a portion of the projecting section as viewed from a direction perpendicular to the other surface of the substrate.
(14)

The semiconductor module according to any one of (11) to (13), further including:
a second semiconductor chip mounted on an inner wall of the projecting section.
(15)

The semiconductor module according to (5), in which the substrate includes
a wiring layer configured to have the semiconductor package mounted on one of two surfaces of the substrate,
a connector mounted on the other surface of the substrate in a manner projecting in a direction perpendicular to the other surface, and
a shield layer configured to cover an inner wall of the connector.
(16)

An electronic device including:
a semiconductor package including
a semiconductor chip configured to have one of two surfaces thereof mounted with a circuit, the circuit formation surface constituting a circuit formation surface,
a first shield layer configured to cover a side of the semiconductor chip and the other surface thereof, and
a second shield layer configured to cover the circuit formation circuit; and
a substrate configured to have the semiconductor chip mounted thereon.
(17)

A semiconductor package manufacturing method including:
a procedure of causing a second shield layer to cover one of two surfaces of a semi-conductor chip, the one surface constituting a circuit formation surface; and
a procedure of causing a first shield layer to cover a side of the semiconductor chip and the other surface thereof.
(18)

A semiconductor package, comprising:
a semiconductor chip, including:
a first surface;
a second surface opposite the first surface; and
one or more side surfaces provided between the first surface and the second surface,
wherein one of the first surface or the second surface has a circuit mounted thereon;
a first shield layer covering the one or more side surfaces and the other of the first surface or the second surface of the semiconductor chip; and
a second shield layer covering the one of the first surface or the second surface of the semiconductor chip having the circuit mounted thereon,
wherein the second shield layer includes at least one metal.
(19)

The semiconductor package according to (18) further comprising:
an under-bump metal,
wherein the second shield layer is provided beneath the under-bump metal.
(20)

The semiconductor package according to (19) further comprising:
an insulating layer provided between the one of the first surface or the second surface of the semiconductor chip having the circuit mounted thereon and the second shield layer,
wherein the second shield layer covers the insulating layer except for a region defined by the under-bump metal.
(21)

The semiconductor package according to (18) further comprising:
a redistribution layer formed on the one of the first surface or the second surface of the semiconductor chip,
wherein redistribution layer occupies an area other than an area underneath the circuit.
(22)

A semiconductor module, comprising:
a substrate; and
a semiconductor package mounted on the substrate,
wherein the semiconductor package includes:
a first semiconductor chip, including:
a first surface;
a second surface opposite the first surface; and
one or more side surfaces provided between the first surface and the second surface,
wherein one of the first surface or the second surface has a first circuit mounted thereon;
a first shield layer covering the one or more side surfaces and the other of the first surface or the second surface of the first semiconductor chip; and
a second shield layer covering the one of the first surface or the second surface of the first semiconductor chip having the first circuit mounted thereon,
wherein the second shield layer includes at least one metal.
(23)

The semiconductor module according to (22) further comprising:
a signal via penetrating the substrate; and
a plurality of ground vias penetrating the substrate,
wherein the plurality of ground vias surround the signal via.
(24)

The semiconductor module according to (22) and (23) further comprising:
a second circuit provided within the semiconductor module,
wherein the first circuit and the second circuit are each connected to a different ground.
(25)

The semiconductor module according to (22)-(24) wherein the second circuit is mounted to the substrate.
(26)

The semiconductor module according to (22)-(25) wherein the semiconductor package is provided above the second circuit.
(27)

The semiconductor module according to (22)-(26) further comprising: a covering provided around the semiconductor package.
(28)

The semiconductor module according to (22) wherein the substrate includes:
a wiring layer having a first surface and a second surface with the first surface of the wiring layer mounted to the semiconductor package;
at least one projection projecting from the second surface of the wiring layer;
a shield layer covering an inner wall of the at least one projection; and
a signal via penetrating the at least one projection.
(29)

The semiconductor module according to (28) wherein the substrate further includes:
a heat dissipator disposed on the second surface of the wiring layer underneath the semiconductor package, and
a ground via penetrating the heat dissipator and having ground potential.
(30)

The semiconductor module according to (22) and (28) further comprising:
an integrated circuit disposed on the second surface of the wiring layer,
the integrated circuit is surrounded by the at least one projection.
(31)

The semiconductor module according to (28) further comprising:
a second semiconductor chip mounted on an inner wall of the at least one projection.
(32)

The semiconductor module according to claim (22) wherein the substrate includes:
a wiring layer having a first surface and a second surface with the first surface of the wiring layer mounted to the semiconductor package;
a connector mounted to the second surface of the wiring layer; and
a shield layer covering an inner wall of the connector.
(33)

The semiconductor module according to (24) wherein the semiconductor package is provided adjacent to the second circuit.
(34)

The semiconductor module according to (24) further comprising:
a partition provided between the semiconductor package and the second circuit.
(35)

The semiconductor module according to (28) wherein the at least one projection is provided on side parts of the second surface of the wiring layer.
(36)

An electronic device, comprising:
a substrate; and
a semiconductor package mounted on the substrate,
wherein the semiconductor package includes:
a semiconductor chip, including:
a first surface;
a second surface opposite the first surface; and
one or more side surfaces provided between the first surface and the second surface,
wherein one of the first surface or the second surface has a circuit mounted thereon;
a first shield layer covering the one or more side surfaces and the other of the first surface or the second surface of the semiconductor chip; and
a second shield layer covering the one of the first surface or the second surface of the semiconductor chip having the circuit mounted thereon,
wherein the second shield layer includes at least one metal.
(37)

The electronic device according to (36) further comprising:
a signal via penetrating the substrate; and
a plurality of ground vias penetrating the substrate,
wherein the plurality of ground vias surround the signal via.
(38)

The electronic device according to (36) and (37) further comprising:
a second circuit provided within the electronic device,
wherein the first circuit and the second circuit are each connected to a different ground.
(39)

The electronic device according to (36)-(38) wherein the second circuit is mounted to the substrate.
(40)

The electronic device according to (38)-(39) wherein the semiconductor package is provided above the second circuit.
(41)

The electronic device according to (36)-(40) further comprising:
a covering provided around the semiconductor package.
(42)

A semiconductor package manufacturing method comprising:
covering by a second shield layer, one of a first surface or a second surface of a semi-conductor chip having a circuit mounted thereon,
wherein the first surface is opposite the second surface; and
covering by a first shield layer, the other of the first surface or the second surface of the semiconductor chip and one or more side surfaces of the semiconductor chip provided between the first surface and second surface of the semiconductor chip,
wherein the second shield layer includes at least one metal.

It should be understood by those skilled in the art that various modifications, combinations, sub-combinations and alterations may occur depending on design requirements and other factors insofar as they are within the scope of the appended claims or the equivalents thereof.

### REFERENCE SIGNS LIST

100: Electronic device
110: Main CPU
111: Menu processing section
112: Application processing section
120: System controller
121: Operation input receiving section
122: Communication processing section
123: Power control section
130: Setting information holding section
200: Semiconductor module
211: Mold resin
212, 331, 340, 362: Shied layer
213: Shield
220: Frame substrate
221: Wiring layer
222: Through via
222-1: Signal via
222-2: Ground via
223: Passive component
224, 352: Solder ball
225: Digital circuit
231, 233: Power supply
232, 234: Ground
240: Substrate
241: Wiring layer
241-1, 241-2: Rewiring
251: Projecting section
252: Heat dissipating section
253: Metallic film
254-1: Signal via
254-2: Ground via
261: Integrated circuit
262, 263: Semiconductor chip
271: Connector
300: Semiconductor package
310: Wafer
311: Semiconductor chip
321: Pad
322: Passivation layer
323, 325: Insulating layer
324, 330: Seed layer
351: Under-bump metal
361: RDL
371: Analog circuit
400: Resist
12031: Imaging section

What is claimed is:

1. A semiconductor package, comprising:
a semiconductor chip, including:
a first surface;
a second surface opposite the first surface; and
one or more side surfaces provided between the first surface and the second surface,
wherein one of the first surface or the second surface has a circuit mounted thereon;
a first shield layer covering the one or more side surfaces and the other of the first surface or the second surface of the semiconductor chip; and
a second shield layer covering the one of the first surface or the second surface of the semiconductor chip having the circuit mounted thereon,
wherein the second shield layer includes at least one metal.

2. The semiconductor package according to claim 1, further comprising:
an under-bump metal,
wherein the second shield layer is provided beneath the under-bump metal.

3. The semiconductor package according to claim 2, further comprising:
an insulating layer provided between the one of the first surface or the second surface of the semiconductor chip having the circuit mounted thereon and the second shield layer,
wherein the second shield layer covers the insulating layer except for a region defined by the under-bump metal.

4. The semiconductor package according to claim 1, further comprising:
a redistribution layer formed on the one of the first surface or the second surface of the semiconductor chip,
wherein redistribution layer occupies an area other than an area underneath the circuit.

5. A semiconductor module, comprising:
a substrate; and
a semiconductor package mounted on the substrate,
wherein the semiconductor package includes:
a first semiconductor chip, including:
a first surface;
a second surface opposite the first surface; and
one or more side surfaces provided between the first surface and the second surface,
wherein one of the first surface or the second surface has a first circuit mounted thereon;
a first shield layer covering the one or more side surfaces and the other of the first surface or the second surface of the first semiconductor chip; and
a second shield layer covering the one of the first surface or the second surface of the first semiconductor chip having the first circuit mounted thereon, wherein the second shield layer includes at least one metal.

6. The semiconductor module according to claim 5, further comprising:
a signal via penetrating the substrate; and
a plurality of ground vias penetrating the substrate,
wherein the plurality of ground vias surround the signal via.

7. The semiconductor module according to claim 5, further comprising:
a second circuit provided within the semiconductor module,
wherein the first circuit and the second circuit are each connected to a different ground.

8. The semiconductor module according to claim 7, wherein the second circuit is mounted to the substrate.

9. The semiconductor module according to claim 7, wherein the semiconductor package is provided above the second circuit.

10. The semiconductor module according to claim 9, further comprising:
a covering provided around the semiconductor package.

11. The semiconductor module according to claim 5, wherein the substrate includes:
a wiring layer having a first surface and a second surface with the first surface of the wiring layer mounted to the semiconductor package;
at least one projection projecting from the second surface of the wiring layer;
a shield layer covering an inner wall of the at least one projection; and
a signal via penetrating the at least one projection.

12. The semiconductor module according to claim 11, wherein the substrate further includes:
a heat dissipator disposed on the second surface of the wiring layer underneath the semiconductor package, and
a ground via penetrating the heat dissipator and having ground potential.

13. The semiconductor module according to claim 11, further comprising:
an integrated circuit disposed on the second surface of the wiring layer,
the integrated circuit is surrounded by the at least one projection.

14. The semiconductor module according to claim 11, further comprising:
a second semiconductor chip mounted on an inner wall of the at least one projection.

15. The semiconductor module according to claim 5, wherein the substrate includes:
a wiring layer having a first surface and a second surface with the first surface of the wiring layer mounted to the semiconductor package;
a connector mounted to the second surface of the wiring layer; and
a shield layer covering an inner wall of the connector.

16. The semiconductor module according to claim 7, wherein the semiconductor package is provided adjacent to the second circuit.

17. The semiconductor module according to claim 7, further comprising:
a partition provided between the semiconductor package and the second circuit.

18. The semiconductor module according to claim 11, wherein the at least one projection is provided on side parts of the second surface of the wiring layer.

19. An electronic device, comprising:
a substrate; and
a semiconductor package mounted on the substrate,
wherein the semiconductor package includes:
a semiconductor chip, including:
a first surface;
a second surface opposite the first surface; and
one or more side surfaces provided between the first surface and the second surface,
wherein one of the first surface or the second surface has a circuit mounted thereon;
a first shield layer covering the one or more side surfaces and the other of the first surface or the second surface of the semiconductor chip; and
a second shield layer covering the one of the first surface or the second surface of the semiconductor chip having the circuit mounted thereon,
wherein the second shield layer includes at least one metal.

20. The electronic device according to claim 19, further comprising:
a signal via penetrating the substrate; and
a plurality of ground vias penetrating the substrate,
wherein the plurality of ground vias surround the signal via.

21. The electronic device according to claim 19, further comprising:
a second circuit provided within the electronic device,
wherein the first circuit and the second circuit are each connected to a different ground.

22. The electronic device according to claim 21, wherein the second circuit is mounted to the substrate.

23. The electronic device according to claim 21, wherein the semiconductor package is provided above the second circuit.

24. The electronic device according to claim 23, further comprising:
a covering provided around the semiconductor package.

25. A semiconductor package manufacturing method, comprising:
covering by a second shield layer, one of a first surface or a second surface of a semiconductor chip having a circuit mounted thereon,
wherein the first surface is opposite the second surface; and
covering by a first shield layer, the other of the first surface or the second surface of the semiconductor chip and one or more side surfaces of the semiconductor chip provided between the first surface and second surface of the semiconductor chip,
wherein the second shield layer includes at least one metal.
